(19) United States
(12) Patent Application Publication
(10) Pub. No.: US 2026/0346754 A1
(43) Pub. Date: Nov. 5, 2026

(54) INITIALIZATION CONTROL FOR STATE OF POWER CALCULATION RATE LIMITERS IN ELECTRIFIED VEHICLES

(71) Applicant: FCA US LLC, Auburn Hills, MI (US)

(72) Inventors: Andrew Philip White, Auburn Hills, MI (US); Youchang Sun, Windsor (CA); Wenzhou Li, Windsor (CA)

(21) Appl. No.: 19/195,042

(22) Filed: Apr. 30, 2025

(51) Int. Cl. B60L 58/12; G01R 31/371; G01R 31/374; G01R 31/3842

(52) U.S. Cl. CPC B60L 58/12; G01R 31/371; G01R 31/374; G01R 31/3842

(57) ABSTRACT

State of power (SOP) calculation systems and methods for a high voltage battery system of an electrified vehicle include a wireless battery pack control module (BPCM) configured to receive, from sensors for the battery system via a wireless communication link, parameters of the battery system, determine, based on the parameters, power limits for the battery system and arbitrate the power limits to calculate a SOP of the battery system, detect an initialization condition when (i) a set of the parameters pass a rationality check and (ii) an estimated state of charge (SOC) for the high voltage battery system is valid, in response to detecting the initialization condition, initialize a rate limiter that rate limits a change in the calculated SOP of the battery system to obtain a rate limited SOP, and control operation of the electrified vehicle based on the rate limited SOP for the battery system.

### FIELD

The present application generally relates to electrified vehicles and, more particularly, to an initialization condition for state of power (SOP) calculation rate limiters in electrified vehicles.

### BACKGROUND

An electrified vehicle includes a high voltage battery pack or system that is configured to power one or more electric traction motors for vehicle propulsion. The battery system includes a plurality of battery modules, each of which includes a plurality of battery cells. A battery pack control module (BPCM) is a specific vehicle controller that receives measured parameters (voltage, current, temperature, etc.) from a plurality of sensors associated with the battery system and that calculates or estimates other parameters for the battery system (state of charge, or SOC, state of power, or SOP, etc.). SOP is a critical parameter for controlling the electrified powertrain and thus the SOP calculation is often rate-limited to prevent drastic changes in the calculated SOP during vehicle operation. In some scenarios, however, the calculated SOP can be initialized at and rate-limited from an abnormally low value. Accordingly, while such conventional electrified vehicle SOP calculation and control systems do work for their intended purpose, there exists an opportunity for improvement in the relevant art.

### SUMMARY

According to one example aspect of the invention, a state of power (SOP) calculation system for a high voltage battery system of an electrified vehicle is presented. In one exemplary implementation, the SOP calculation system comprises sensors configured to measure parameters of the battery system and a wireless battery pack control module (BPCM) configured to establish a wireless communication link with the sensors and to receive, from the sensors via the wireless communication link, the measured parameters, determine, based on the parameters, power limits for the battery system and arbitrate the power limits to calculate a SOP of the battery system, detect an initialization condition when (i) a set of the parameters pass a rationality check and (ii) an estimated state of charge (SOC) for the high voltage battery system is valid, in response to detecting the initialization condition, initialize a rate limiter that rate limits a change in the calculated SOP of the battery system to obtain a rate limited SOP, and control operation of the electrified vehicle based on the rate limited SOP for the battery system.

In some implementations, the rationality check includes the BPCM determining whether an estimated open-circuit voltage (OCV) and an estimated resistance of the battery system satisfy a set of rationality constraints. In some implementations, the BPCM is further configured to (i) estimate the OCV, the resistance, and the estimated SOC of the battery system based on the measured parameters and (ii) determine the validity of the SOC estimation or generate an SOC validity signal. In some implementations, the measured parameters include a measured voltage, a measured current, and a measured temperature of the battery system. In some implementations, the power limits for the battery system include an adaptive power limit and a map based power limit. In some implementations, the BPCM is further configured to calculate the adaptive power limit based on the measured current, the measured voltage, and the measured temperature of the battery system.

In some implementations, the BPCM is further configured to calculate the map based power limit based on the measured temperature and the estimated SOC of the battery system. In some implementations, the BPCM is configured to arbitrate the power limits to obtain the calculated SOP by determining, for discharge conditions, a maximum of the adaptive and map based power limits or, for charge conditions, a minimum of the adaptive and map based power limits. In some implementations, signals indicating results of the rationality check and the estimated SOC validity are fed to an AND gate, which is used by the BPCM to generate a latch signal, indicating satisfaction of the initialization condition, for enabling or initializing the rate limiter for the calculated SOP. In some implementations, the BPCM is further configured to selectively derate the rate limited SOP of the battery system based on a set of derate conditions.

According to another aspect of the invention, an SOP calculation method for a high voltage battery system of an electrified vehicle is presented. In one exemplary implementation, the SOP calculation method comprises establishing, between a wireless BPCM and sensors of the electrified vehicle, a wireless communication link, wherein the sensors are configured to measure parameters of the battery system, receiving, by the BPCM and from the sensors via the wireless communication link, the measured parameters, determining, by the BPCM and based on the parameters, power limits for the battery system and arbitrate the power limits to calculate a SOP of the battery system, detecting, by the BPCM, an initialization condition when (i) a set of the parameters pass a rationality check and (ii) an estimated SOC for the high voltage battery system is valid, in response to detecting the initialization condition, initializing, by the BPCM, a rate limiter that rate limits a change in the calculated SOP of the battery system to obtain a rate limited SOP, and controlling, by the BPCM, operation of the electrified vehicle based on the rate limited SOP for the battery system.

In some implementations, the rationality check includes determining, by the BPCM, whether an estimated OCV and an estimated resistance of the battery system satisfy a set of rationality constraints. In some implementations, the SOP calculation method further comprises (i) estimating, by the BPCM, the OCV, the resistance, and the estimated SOC of the battery system based on the measured parameters and (ii) determining, by the BPCM, the validity of the SOC estimation or generate an SOC validity signal. In some implementations, the measured parameters include a measured voltage, a measured current, and a measured temperature of the battery system. In some implementations, the power limits for the battery system include an adaptive power limit and a map based power limit. In some implementations, the SOP calculation method further comprises calculating, by the BPCM, the adaptive power limit based on the measured current, the measured voltage, and the measured temperature of the battery system.

In some implementations, the SOP calculation method further comprises calculating, by the BPCM, the map based power limit based on the measured temperature and the estimated SOC of the battery system. In some implementations, the arbitrating of the power limits to obtain the calculated SOP comprises determining, by the BPCM, for discharge conditions, a maximum of the adaptive and map based power limits or, for charge conditions, a minimum of the adaptive and map based power limits. In some implementations, signals indicating results of the rationality check and the estimated SOC validity are fed to an AND gate, which is used by the BPCM to generate a latch signal, indicating satisfaction of the initialization condition, for enabling or initializing a rate limiter for the calculated SOP. In some implementations, the SOP calculation method further comprises selectively derating, by the BPCM, the rate limited SOP of the battery system based on a set of derate conditions.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an electrified vehicle having a high voltage battery system and an example state of power (SOP) calculation system according to the principles of the present application;

FIG. 2 is a functional block diagram of an example system architecture for the example SOP calculation system according to the principles of the present application;

FIGS. 3A-3C are example plots of an intended SOP calculation rate limiting, a problematic SOP calculation rate limiting, and an SOP calculation rate limiting according to the principles of the present application; and

FIG. 4 is a flow diagram of example SOP calculation method for a high voltage battery system of an electrified vehicle according to the principles of the present application.

### DESCRIPTION

As previously discussed, an electrified vehicle includes a high voltage battery pack or system that is configured to power one or more electric traction motors for vehicle propulsion. The battery system includes a plurality of battery modules, each of which includes a plurality of battery cells. A battery pack control module (BPCM) is a specific vehicle controller that receives measured parameters (voltage, current, temperature, etc.) from a plurality of sensors associated with the battery system and that calculates or estimates various parameters for the battery system (state of charge, or SOC, state of power, or SOP, etc.). SOP is a critical parameter for controlling the electrified powertrain (e.g., for charge/discharge limits of the battery system) and thus the SOP calculation is often rate-limited to prevent drastic changes in the calculated SOP during vehicle operation. In some scenarios, however, the calculated SOP can be initialized at and rate-limited from an abnormally low value (zero, a negative value, etc.). This could occur, for example, during a key-on or wakeup event of the electrified vehicle and could result in an abnormally long ramp-up period to a normal SOP value, which could be noticeable and aggravating to consumers.

In one particular electrified vehicle embodiment, the BPCM is a wireless BPCM. More specifically, the BPCM is configured to communicate via one or more short-range wireless communication mediums (Bluetooth, WiFi Direct, Zigbee, etc.), such as with the sensors and/or a central controller or controller area network (CAN) of the electrified vehicle. Due to its wireless connectivity, the wireless BPCM could temporarily lose communication with the sensors, thereby causing the temporarily invalid sensor measurements. This establishment of wireless communication between the wireless BPCM and other electrified vehicle components (e.g., the sensors for the battery system) could also increase a length or duration of the key-on or wakeup period of the electrified vehicle (i.e., for purposes of waiting for valid measurements to initialize the SOP calculation and rate limiters). In other words, the wireless BPCM could exacerbate an already abnormally low initial SOP calculation and ramp-up thereafter, which would be even more noticeable and aggravating to consumers.

Accordingly, improved SOP calculation systems and methods are presented herein. These improved SOP calculation systems and methods utilize a validity signal indicative of a state of charge (SOC) calculation for the battery system (hereinafter, “SOC validity signal”) as an enabler for initializing the downstream rate limiters for the SOP calculation. The SOC can be deemed valid when it conforms to expectations (e.g., past values and current conditions, such as battery temperature and open-circuit voltage, or OCV). The SOP calculation also performs an initial rationality check based on rationality constraints for the measured parameters (OCV, resistance, etc.). These rationality constraints are designed to ensure that the SOP calculation is at least a rational value (not zero, not a negative value for discharge limits, etc.). The output of this rationality check is combined with the SOC validity signal (e.g., an AND gate) and, when both conditions are satisfied, the downstream rate limiters are initialized. The initial SOP calculation that is provided to the downstream rate limiters can be a maximum of adaptive power limits (based on current, voltage, and temperature), and map based power limits (based on temperature and SOC).

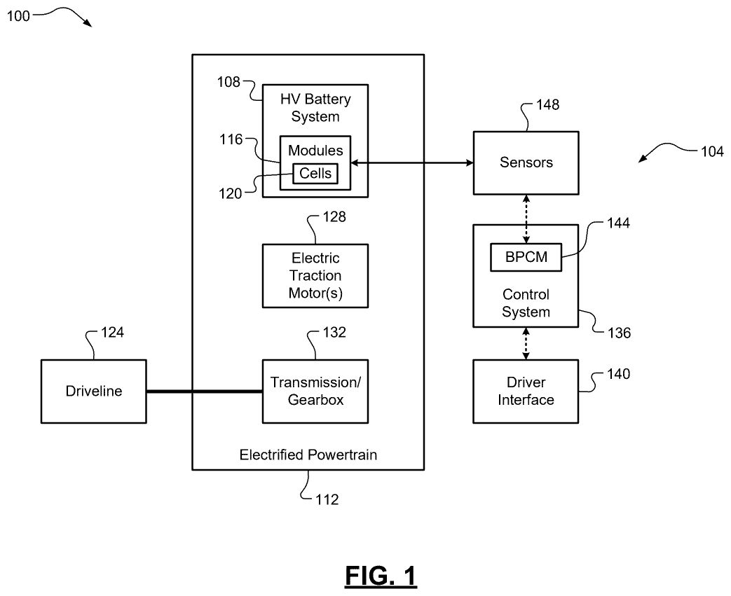

Referring now to FIG. 1, a functional block diagram of an electrified vehicle 100 having an example thermal runaway monitoring system 104 for a high voltage (HV) battery system 108 according to the principles of the present application is illustrated. The HV battery system 108 (also “battery system 108” herein) is part of an electrified powertrain 112 of the electrified vehicle 100 and the battery system 108 further comprises a plurality of battery modules 116 each comprising a plurality of battery cells 120. It will be appreciated that the battery system 108 could have any suitable configuration (e.g., a 400V or 800V DC battery system, which could comprise, for example only, 13 battery modules each having 8 lithium-ion type battery cells). The electrified powertrain 112 is configured to generate and transfer drive torque to a driveline 124 for vehicle propulsion. More specifically, one or more electric traction motors 128 (e.g., one or more interior permanent magnet synchronous motors) are configured to be powered by the battery system 108 (e.g., via a three-phase inverter) and the electric traction motor(s) 128 is/are configured to generate drive torque that can be transferred to the driveline 124 via an optional transmission, gearbox, or gear reducer 132.

A control system 136, which comprises a plurality of controllers or electronic control units (ECUs) connected or in communication with each other via a controller area network (CAN) or other suitable network, controls operation of the electrified vehicle 100, which primarily includes controlling the electrified powertrain 112 to generate and transfer to the driveline 124 a sufficient amount of drive torque to satisfy a driver torque request (e.g., received from a driver of the electrified vehicle 100 via a driver interface 140, such as an accelerator pedal device). For purposes of the present application, the control system 136 is shown to specifically include a BPCM 144, which controls/monitors the battery system 108, including receiving parameter measurements of the modules 116 or cells 120 via a plurality of sensors 148 (also “sensors 148” herein). It will be appreciated that the control system 136 could further include other modules/ECUs, such as a supervisory ECU (e.g., an electrified vehicle control unit, or EVCU), motor/transmission controllers or ECUs, and the like. The control system 136 (or, more specifically, the BPCM 144) is further configured to execute at least a portion of the SOP calculation techniques of the present application. As mentioned above, the BPCM 144 receives measured parameters from the sensors 148.

Based on these measured parameters (current, voltage, temperature, etc.), the BPCM 144 can also estimate other parameters of the battery system 108, such as SOC (e.g., using a Kalman filter), OCV, and resistance. The measured parameters from the sensors 148 can at times be invalid (as opposed to valid). This could be the result of hardware malfunctions or due to a communication fault or malfunction (e.g., a break or interruption in a communication link between the BPCM 144 and the sensors 148). This can also occur at key-on or wakeup events of the BPCM 144. In one example embodiment, the BPCM 144 is a wireless BPCM that wirelessly communicates with the sensors 148 via a short-range wireless communication medium (Bluetooth, WiFi Direct, Zigbee, etc.) and this communication link could temporarily break or be interrupted and then subsequently reestablished. A wireless implementation for the BPCM 144 allows for more flexible vehicle packaging, but it also presents the challenges discussed in detail herein due to temporary communication losses.

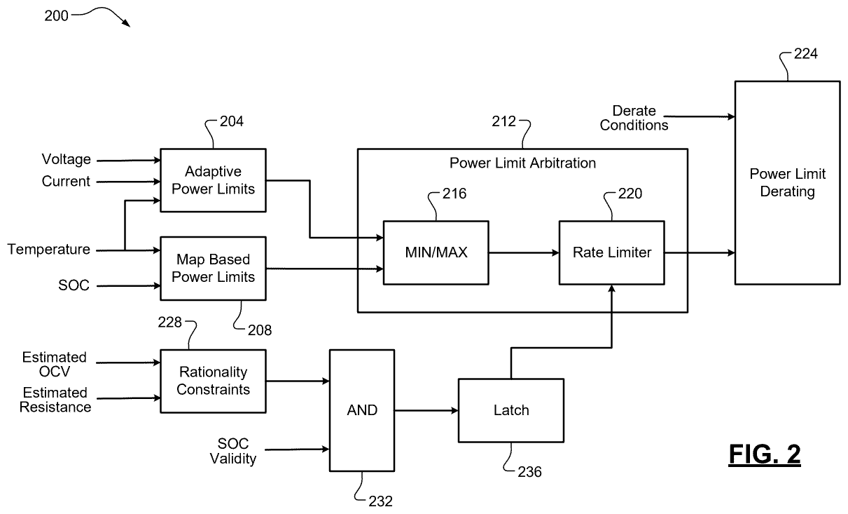

Referring now to FIG. 2 and with continued reference to FIG. 1, a functional block diagram of an example system architecture 200 for the example SOP calculation system 104 according to the principles of the present application is illustrated. An adaptive power limits block 204 receives measured voltage, current, and temperature (from sensors 148) and calculates an adaptive power limit for the battery system. A map based power limits block 208 receives measured temperature (from sensors 148) and the calculated or estimated SOC for the battery system 108 and calculates a map based power limit (e.g., using a two-dimensional look-up table or surface based on the two inputs). These two power limits are both fed to a power limit arbitration block 212 and, more particularly, to a MIN/MAX block 216 that determines or arbitrates a minimum or maximum of these two power limits. For discharge power limits (positive values), the MIN/MAX block 216 will arbitrate and output the maximum of the two power limits. For charge power limits (negative values), however, the MIN/MAX block 216 will arbitrate and output the minimum of the two power limits. The arbitrated power limit is output to a rate limiter block 220 of the power limit arbitration block 212, which selectively (i.e., based on an enable or latch signal) rate limits the arbitrated power limit output. The selectively rate-limited arbitrated power limit is thereafter limit derated based on a set of derate conditions, and the final calculated SOP value is then broadcast to other modules/ECUs of the electrified vehicle 100 for usage.

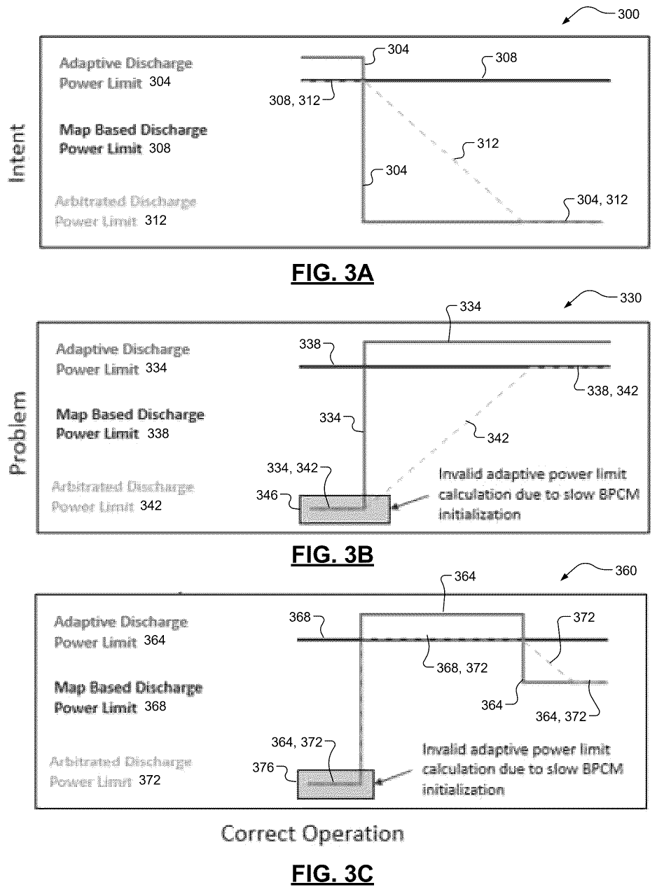

Referring now to FIGS. 3A-3C and with continued reference to FIG. 2, example plots 300, 330, and 360 of an intended SOP calculation rate limiting, a problematic SOP calculation rate limiting, and an SOP calculation rate limiting according to the principles of the present application, respectively, are illustrated. While FIGS. 3A-3C illustrate example plots for discharge power limits, it will be appreciated that the techniques of the present application are also applicable to calculation of the SOP in relation to charge power limits. In FIG. 3A, an example plot 300 illustrates the intended SOP calculation rate limiting. Initially, the adaptive discharge power limit 304 is greater than the map based discharge power limit 308 and the arbitrated discharge power limit 312 equals the map based discharge power limit 308. When the adaptive discharge power limit 304 then drops below the map based discharge power limit, the arbitrated discharge power limit 312 is rate limited from the map based discharge power limit 308 to the adaptive discharge power limit 304. Once the adaptive discharge power limit 312 reaches the lower adaptive discharge power limit 304, the arbitrated discharge power limit 312 remains equal to the adaptive discharge power limit.

In FIG. 3B, however, an example plot 330 of a problematic SOP calculation rate limiting is illustrated. Initially, the adaptive discharge power limit 334 is lower than the map based discharge power limit 338 and the arbitrated discharge power limit 342 equals the lower adaptive discharge power limit 334. This adaptive discharge power limit 334, however, is initially invalid due to slow initialization of the BPCM 144 (e.g., wireless communication establishment). In this problematic scenario, this invalid initialization of the rate limiter causes the arbitrated discharge power limit 342 to slowly increase up to the map based discharge power limit 338 once the adaptive discharge power limit 334 becomes valid and increases up above the map based discharge power limit 338. In FIG. 3C, an example plot 360 of the correct(ed) operation according to the techniques of the present application is illustrated. This involves rationality constraints 228 being applied (e.g., a rationality check) on the estimated OCV and estimated resistance (i.e., to determine that they are rational values and not unreasonable). The output of this rationality check at block 228 is output (e.g., HIGH=pass) to an AND block 232 along with the SOC validity signal (e.g., HIGH=valid). Thus, the output of the AND gate 232 goes HIGH when both of these are true, which is latched via latch block 236 to the initialize the rate limiter 220 (which would otherwise not be initialized without these two conditions being satisfied). The result is the desired example plot 360 showing the correct or desired SOP calculation.

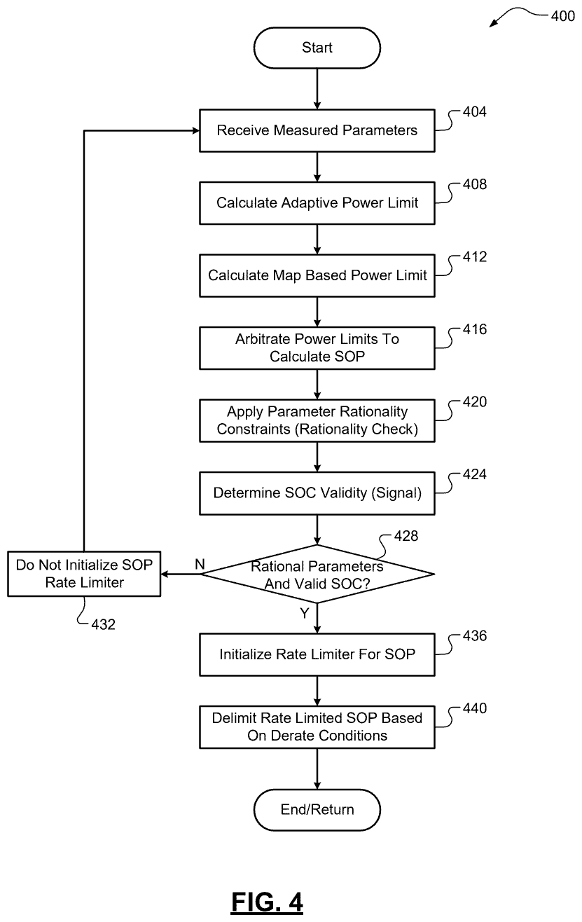

Referring now to FIG. 4 and with continued reference to the previous figures, a flow diagram of an example SOP calculation method 400 for a high voltage battery system of an electrified vehicle according to the principles of the present application is illustrated. While the method 400 specifically references the electrified vehicle 100 and its components (e.g., the battery system 108 and the BPCM 144), it will be appreciated that the method 400 could be applicable to any suitably configured electrified vehicle having a high voltage battery system with temperature sensor(s) and a wireless BPCM. The method 400 begins at 404 where the BPCM 144 receives measured parameters from the sensors 148. Provided there is an established, functional wireless communication link between the BPCM 144 and the sensors 148, the measured parameters should be valid (except for cases of sensor faults or other hardware malfunctions). As discussed above, these parameters can include voltage, current, and temperature, and other parameters that cannot be directly measured by the sensors 148 can be estimated based on the measurable parameters, such as SOC, OCV, and resistance. At 408, the BPCM 144 calculated an adaptive power limit (see block 204 of FIG. 2) as previously described. At 412, the BPCM 144 calculates a map based power limit (see block 208 of FIG. 2) as previously described.

At 416, the BPCM 144 arbitrates the power limits (i.e., the minimum or maximum of the two calculated power limits, depending on whether for charge or discharge) to calculate the SOP for the battery system 108 (see blocks 212 and 216 of FIG. 2). At 420, the BPCM 144 applies parameter rationality constraints (i.e., a rationality check) to the measured parameters (see block 228 of FIG. 2). At 424, the BPCM 144 determines a validity of the SOC or determines a status (e.g., HIGH being valid, LOW being invalid) of the SOC validity signal. At 428, the BPCM 2144 determines whether the parameters passed the rationality check/constraints and the SOC is valid. When false, the method 400 proceeds to 432 where the downstream SOP rate limiter is not initialized (see blocks 220 and 236 of FIG. 2) and the method 400 ends or returns to 404 (e.g., until the SOC eventually becomes valid). When true, the method 400 proceeds to 436 where the downstream SOP rate limiter is initialized (see blocks 220 and 236 of FIG. 2) and the method 400 proceeds to 440. At 440, the rate-limited SOP is derated based on a set of derate conditions (see block 224 of FIG. 2). The method 400 then ends or returns to 404 for one or more additional cycles (e.g., at a next key-on or wakeup event of the electrified vehicle 100 and the BPCM 144).

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. A state of power (SOP) calculation system for a high voltage battery system of an electrified vehicle, the SOP calculation system comprising:
sensors configured to measure parameters of the battery system; and
a wireless battery pack control module (BPCM) configured to establish a wireless communication link with the sensors and to:
receive, from the sensors via the wireless communication link, the measured parameters;
determine, based on the parameters, power limits for the battery system and arbitrate the power limits to calculate a SOP of the battery system;
detect an initialization condition when (i) a set of the parameters pass a rationality check and (ii) an estimated state of charge (SOC) for the high voltage battery system is valid;
in response to detecting the initialization condition, initialize a rate limiter that rate limits a change in the calculated SOP of the battery system to obtain a rate limited SOP; and
control operation of the electrified vehicle based on the rate limited SOP for the battery system.

2. The SOP calculation system of claim 1, wherein the rationality check includes the BPCM determining whether an estimated open-circuit voltage (OCV) and an estimated resistance of the battery system satisfy a set of rationality constraints.

3. The SOP calculation system of claim 2, wherein the BPCM is further configured to (i) estimate the OCV, the resistance, and the estimated SOC of the battery system based on the measured parameters and (ii) determine the validity of the SOC estimation or generate an SOC validity signal.

4. The SOP calculation system of claim 3, wherein the measured parameters include a measured voltage, a measured current, and a measured temperature of the battery system.

5. The SOP calculation system of claim 4, wherein the power limits for the battery system include an adaptive power limit and a map based power limit.

6. The SOP calculation system of claim 5, wherein the BPCM is further configured to calculate the adaptive power limit based on the measured current, the measured voltage, and the measured temperature of the battery system.

7. The SOP calculation system of claim 6, wherein the BPCM is further configured to calculate the map based power limit based on the measured temperature and the estimated SOC of the battery system.

8. The SOP calculation system of claim 7, wherein the BPCM is configured to arbitrate the power limits to obtain the calculated SOP by determining, for discharge conditions, a maximum of the adaptive and map based power limits or, for charge conditions, a minimum of the adaptive and map based power limits.

9. The SOP calculation system of claim 8, wherein signals indicating results of the rationality check and the estimated SOC validity are fed to an AND gate, which is used by the BPCM to generate a latch signal, indicating satisfaction of the initialization condition, for enabling or initializing the rate limiter for the calculated SOP.

10. The SOP calculation system of claim 9, wherein the BPCM is further configured to selectively derate the rate limited SOP of the battery system based on a set of derate conditions.

11. A state of power (SOP) calculation method for a high voltage battery system of an electrified vehicle, the SOP calculation method comprising:
establishing, between a wireless battery pack control module (BPCM) and sensors of the electrified vehicle, a wireless communication link, wherein the sensors are configured to measure parameters of the battery system;
receiving, by the BPCM and from the sensors via the wireless communication link, the measured parameters;
determining, by the BPCM and based on the parameters, power limits for the battery system and arbitrate the power limits to calculate a SOP of the battery system;
detecting, by the BPCM, an initialization condition when (i) a set of the parameters pass a rationality check and (ii) an estimated state of charge (SOC) for the high voltage battery system is valid;
in response to detecting the initialization condition, initializing, by the BPCM, a rate limiter that rate limits a change in the calculated SOP of the battery system to obtain a rate limited SOP; and
controlling, by the BPCM, operation of the electrified vehicle based on the rate limited SOP for the battery system.

12. The SOP calculation method of claim 11, wherein the rationality check includes determining, by the BPCM, whether an estimated open-circuit voltage (OCV) and an estimated resistance of the battery system satisfy a set of rationality constraints.

13. The SOP calculation method of claim 12, further comprising (i) estimating, by the BPCM, the OCV, the resistance, and the estimated SOC of the battery system based on the measured parameters and (ii) determining, by the BPCM, the validity of the SOC estimation or generate an SOC validity signal.

14. The SOP calculation method of claim 13, wherein the measured parameters include a measured voltage, a measured current, and a measured temperature of the battery system.

15. The SOP calculation method of claim 14, wherein the power limits for the battery system include an adaptive power limit and a map based power limit.

16. The SOP calculation method of claim 15, further comprising calculating, by the BPCM, the adaptive power limit based on the measured current, the measured voltage, and the measured temperature of the battery system.

17. The SOP calculation method of claim 16, further comprising calculating, by the BPCM, the map based power limit based on the measured temperature and the estimated SOC of the battery system.

18. The SOP calculation method of claim 17, wherein the arbitrating of the power limits to obtain the calculated SOP comprises determining, by the BPCM, for discharge conditions, a maximum of the adaptive and map based power limits or, for charge conditions, a minimum of the adaptive and map based power limits.

19. The SOP calculation method of claim 18, wherein signals indicating results of the rationality check and the estimated SOC validity are fed to an AND gate, which is used by the BPCM to generate a latch signal, indicating satisfaction of the initialization condition, for enabling or initializing a rate limiter for the calculated SOP.

20. The SOP calculation method of claim 19, further comprising selectively derating, by the BPCM, the rate limited SOP of the battery system based on a set of derate conditions.
